(19) United States
(12) Patent Application Publication
(10) Pub. No.: US 2026/0068133 A1
(43) Pub. Date: Mar. 5, 2026

(54) SCULPTED TRENCH FOR WORD LINE STRUCTURE FORMATION

(71) Applicant: Micron Technology, Inc., Boise, ID (US)

(72) Inventors: Babak TAHMOURESILERD, Boise, ID (US); Sanjeev SAPRA, Boise, ID (US); Vivek YADAV, Boise, ID (US); Kangle LI, Boise, ID (US); Toshiyasu FUJIMOTO, Hiroshima (JP); XiangYa SU, Taichung City (TW); Po Yen HSU, Houli Township (TW); Ping-Cheng HSU, Hiroshima (JP)

(21) Appl. No.: 19/252,528

(22) Filed: Jun. 27, 2025

Related U.S. Application Data
(60) Provisional application No. 63/687,373, filed on Aug. 27, 2024.

(51) Int. Cl. H10B 12/00

(52) U.S. Cl. CPC H10B 12/34; H10B 12/053

(57) ABSTRACT

Implementations described herein relate to various structures, integrated assemblies, and memory devices. In some implementations, an integrated assembly includes an active area region having an upper portion and a lower portion, where a width of the lower portion is less than a width of the upper portion. The integrated assembly further includes a word line structure horizontally adjacent to the lower portion. Tairn

### CROSS-REFERENCE TO RELATED APPLICATION

This Patent Application claims priority to U.S. Provisional Patent Application No. 63/687,373, filed on Aug. 27, 2024, entitled “SCULPTED TRENCH FOR WORD LINE STRUCTURE FORMATION,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to semiconductor device having a sculpted trench for word line structure formation.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, the electronic device may write, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. A binary memory device may, for example, include a charged or discharged capacitor. A charged capacitor may, however, become discharged over time through leakage currents, resulting in the loss of the stored information. Some features of volatile memory may offer advantages, such as faster read or write speeds, while some features of non-volatile memory, such as the ability to store data without periodic refreshing, may be advantageous.

### BRIEF DESCRIPTION OF THE DRAWINGS

FIG. 1 is a circuit diagram of an example memory cell described herein.

FIGS. 2A and 2B are diagrammatic views illustrating an example implementation of an integrated assembly at different stages of formation.

FIG. 3 is a flowchart of an example method of forming an integrated assembly or memory device having a word line structure formed in sculpted trenches.

FIGS. 4A-4H are diagrammatic views showing formation of a word line structure at stages of an example process described herein.

FIG. 5 is a diagrammatic view of example etch operations described herein.

FIG. 6 is a diagrammatic view of an example memory device.

### DETAILED DESCRIPTION

Dynamic random access memory (DRAM) technology has continually evolved, with a persistent industry-driven goal of shrinking memory cells to achieve higher densities and improved performance. As the industry moves toward smaller geometries, device performance becomes increasingly susceptible to a variety of challenges. One of the prevalent issues is that of managing resistance within the word line (WL) structures of memory cells. Elevated resistance levels can negatively impact the speed and efficiency of memory operations, degrading overall device performance.

In the drive toward improvement, managing the resistance of the word line, controlling leakage, and ensuring high-quality interfaces present technical obstacles that require new and innovative processes. Traditional techniques of memory manufacturing may manufacture a word line structure in a trench that is etched anisotropically, and narrows with a “V-shaped” profile. Such a profile may limit a volume of the word line structure, and increase a resistance of the word line structure, which reduces a performance and a reliability of a memory device including the word line structure.

Some implementations described herein address the challenge of high word line resistance in a memory device by using techniques that sculpt a trench that is subsequently used to form a word line structure. By sculpting the trench, a volume of the word line structure may be increased to reduce word line resistance.

In these ways, the techniques improve a performance and/or a reliability of the memory device by reducing the word line resistance. By improving the performance and//or the reliability of the memory device, resources needed to support a product line using the memory device (e.g., semiconductor manufacturing tools, labor, materials, and/or computing resources) may be conserved.

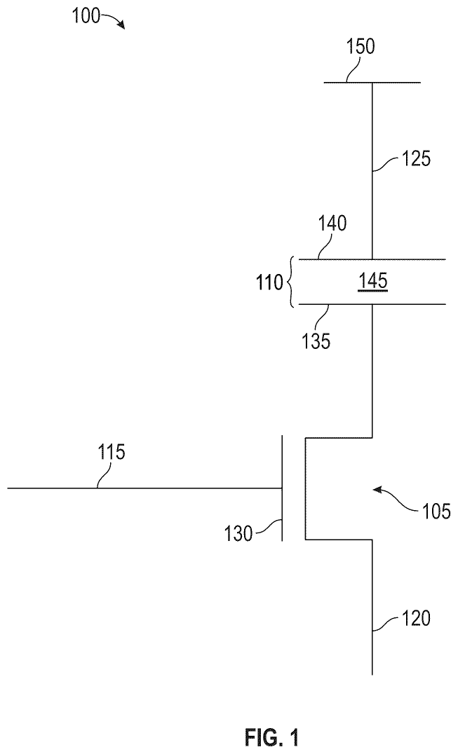

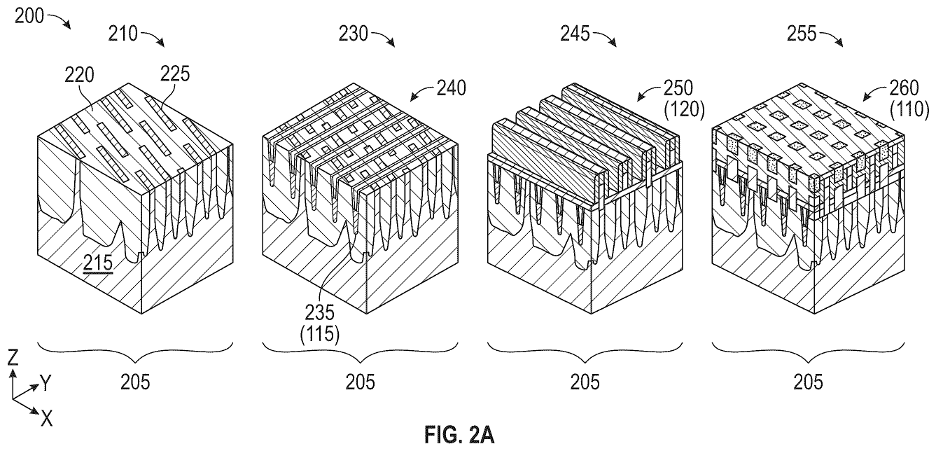

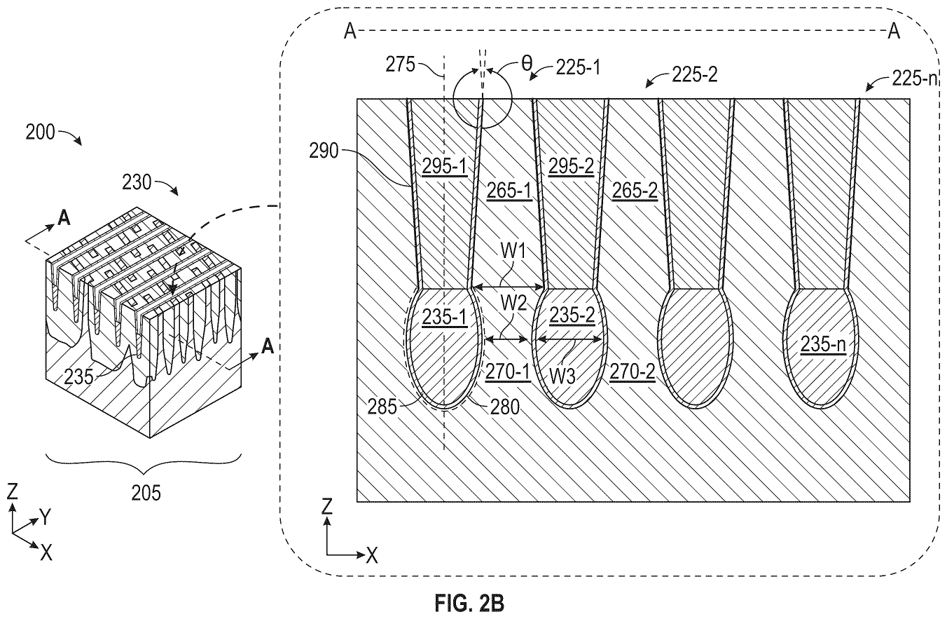

FIG. 1 is a circuit diagram of an example memory cell 100 described herein. In some implementations, the memory cell 100 is a ferroelectric memory cell. Alternatively, the memory cell 100 may be a linear dielectric memory cell or a paraelectric memory cell. As shown in FIG. 1, the memory cell 100 may include a transistor 105 (or another type of selection circuit) and a capacitor 110. The memory cell 100 may be accessed (e.g., written to, read from, and/or erased) using signals on a combination of lines that are coupled to the memory cell 100, shown as an access line 115 (sometimes called a “word line”), a digit line 120 (sometimes called a “bit line”), and a plate line 125. In some implementations, and as described in greater detail in connection with FIGS. 2B-5, the access line 115 (e.g., a word line structure) may be formed in a trench that is sculpted using an isotropic etching process to increase a volume of the access line and reduce a resistance of the access line 115

The transistor 105 (sometimes called an access transistor) may include a gate 130. The capacitor 110 includes a bottom electrode 135 and a top electrode 140 separated by an insulator 145. In some implementations, the capacitor is a ferroelectric capacitor, and the insulator 145 is a ferroelectric insulator that comprises, consists of, or consists essentially of ferroelectric material. Alternatively, the capacitor may be a linear dielectric capacitor, and the insulator 145 may be a linear dielectric insulator that comprises, consists of, or consists essentially of linear dielectric material. Alternatively, the capacitor may be a paraclectric capacitor, and the insulator 145 may be a paraelectric insulator that comprises, consists of, or consists essentially of paraelectric material. When the access line 115 is activated (e.g., when a voltage is applied to the access line 115), the gate 130 coupled to the access line 115 may be activated. When the gate 130 is activated, the transistor 105 couples the digit line 120 to the bottom electrode 135 of the capacitor 110. A state of the memory cell 100 may then be written or read via the digit line 120.

The top electrode 140 of the capacitor 110 may be coupled to the plate line 125 and a cell plate 150. To write to (or program) the memory cell 100, the access line 115 may be activated, and a voltage may be applied across the capacitor 110 by controlling the voltage of the top electrode 140 (via the plate line 125 and/or the cell plate 150) and/or the bottom electrode 135 (via the digit line 120).

To read the memory cell 100 (e.g., a state stored by the capacitor 110), the access line 115 may be activated, and a voltage may be applied to the plate line 125. Applying a voltage to the plate line 125 may cause a change in the stored charge on the capacitor 110. The magnitude of the change in stored charge may depend on the stored state of capacitor 110 (e.g., whether the stored state is a logic “1” state or a logic “0” state). This may or may not induce a threshold change in the voltage of the digit line 120 based on the charge stored on the capacitor 110. The change in voltage or lack of change in voltage of the digit line 120 (or a magnitude of the change in voltage) may be used to determine the stored state of the capacitor 110. For example, if the change in voltage satisfies a threshold, then the read operation indicates that a first state was stored in the capacitor 110, whereas if the change in voltage does not satisfy the threshold, then the read operation determines that a second state was stored in the capacitor 110. In some cases, multiple threshold voltages may be used, such as when the capacitor is capable of storing more than two data states (e.g., for a multi-level cell, a triple-level cell, and so on).

As indicated above, FIG. 1 is provided as an example. Other examples may differ from what is described with respect to FIG. 1.

FIGS. 2A and 2B are diagrammatic views illustrating an example implementation 200 of an integrated assembly 205 at different stages of formation. In some implementations, the integrated assembly 205 is a portion of a semiconductor device, such as a DRAM memory device.

As shown in FIG. 2A, and at stage 210, the integrated assembly 205 includes a substrate 215 and a dielectric region 220 that is over and/or on the substrate 215. The substrate 215 may be a semiconductor and may comprise, consist of, or consist essentially of semiconductive material. The semiconductive material may comprise, consist of, or consist essentially of silicon (e.g., polycrystalline silicon) or a type III-V element, among other examples. The dielectric region 220 may include a combination of dielectric layers, where each dielectric layer is an electrical insulator that may comprise, consist of, or consist essentially of insulative material. The insulative material may comprise, consist of, or consist essentially of silicon dioxide, silicon nitride, silicon dioxide, aluminum oxide, hafnium oxide, or titanium dioxide, among other examples.

In some implementations, and as shown in FIG. 2A, active areas 225 may penetrate into and/or through the dielectric region 220. An active area 225 may include a combination of one or more semiconductive layers, where each semiconductive layer may include a semiconductive material as described above. In some implementations, an active area 225 may be doped with a dopant (e.g., an n-type or a p-type dopant) to change a property of a semiconductive layer. Furthermore, an active area 225 may correspond to circuitry of the integrated assembly 205, such as a channel portion of a transistor included in a memory cell of the integrated assembly 205 (e.g., a channel of the transistor 105 of the memory cell 100 of FIG. 1).

As further shown in FIG. 2A, and at stage 230, the integrated assembly 205 includes word line structures 235 below insulative structures 240 (e.g., the word line structures 235 are buried word line structures). A word line structure 235 (e.g., corresponding to the access line 115 of FIG. 1) may include one or more layers of an electrical conductor that may comprise, consist of, or consist essentially of conductive material. The conductive material may comprise, consist of, or consist essentially of a metal (e.g., titanium, tungsten, cobalt, nickel, platinum, and/or ruthenium), a metal composition (e.g., a metal silicide, a metal carbide, and/or a metal nitride, such as titanium nitride or titanium silicon nitride), a silicide, and/or a conductively-doped semiconductor material (e.g., conductively-doped silicon, conductively-doped germanium, and/or conductively-doped gallium arsenide), among other examples. The insulative structures 240 may include one or more layers of an insulative material as described above.

As further shown in FIG. 2A, and at stage 245, the integrated assembly 205 includes bit line structures 250 over the word line structures 235. In some implementations, the bit line structures 250 are oriented orthogonally to the word line structures 235. A bit line structure 250 (e.g., corresponding to the digit line 120 of FIG. 1) may include one or more layers of a conductive material as described above.

As further shown in FIG. 2A, and at stage 255, the integrated assembly 205 includes a capacitor array structure 260 over the bit line structures 250. The capacitor array structure 260 may include an array of capacitors (e.g., corresponding to the capacitor 110 of FIG. 1) and contact structures. The capacitor array structure 260 may include one or more layers of conductive materials and/or insulative materials as described above.

FIG. 2B shows details of a region of the integrated assembly 205 including multiple word line structures 235. FIG. 2B includes a section view A-A of the word line structures 235 that passes through the active areas 225 of the integrated assembly 205. As shown in FIG. 2B, the trench structures 235-1 through 235-n are formed in sculpted trenches.

The integrated assembly 205 of FIG. 2B includes the active areas 225-1 through 225-n. In some implementations, one or more of the active areas 225-1 through 225-n may include upper portions 265 (e.g., the active area 225-1 includes the upper portion 265-1 and the active area 225-2 includes the upper portion 265-2) and lower portions 270 (e.g., the active area 225-1 includes the lower portion 270-1 and the active area 225-2 includes the lower portion 270-2). As further shown in FIG. 2B, the active area 225-1 is between the word line structures 235-1 and 235-2. Additionally, or alternatively, the word line structures 235-1 and 235-2 are horizontally adjacent to the lower portion 270-1.

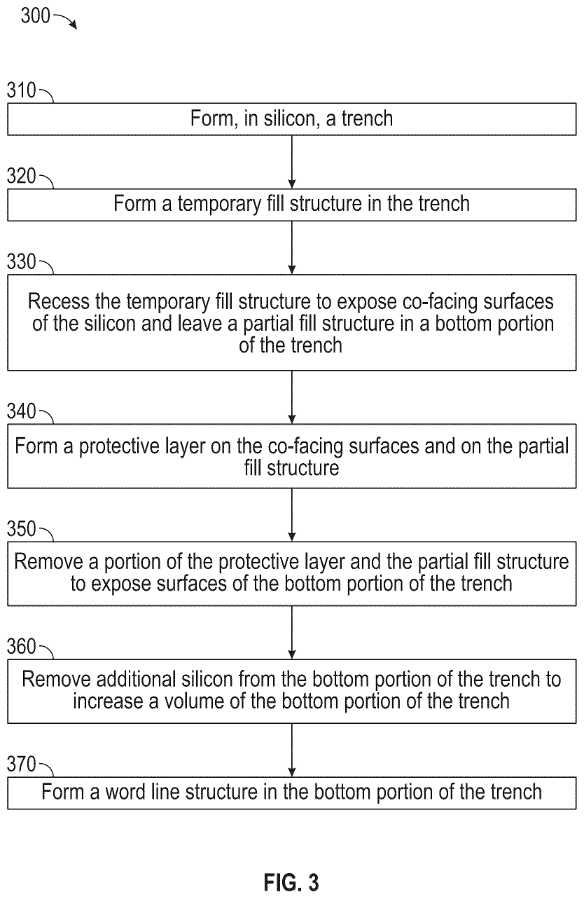

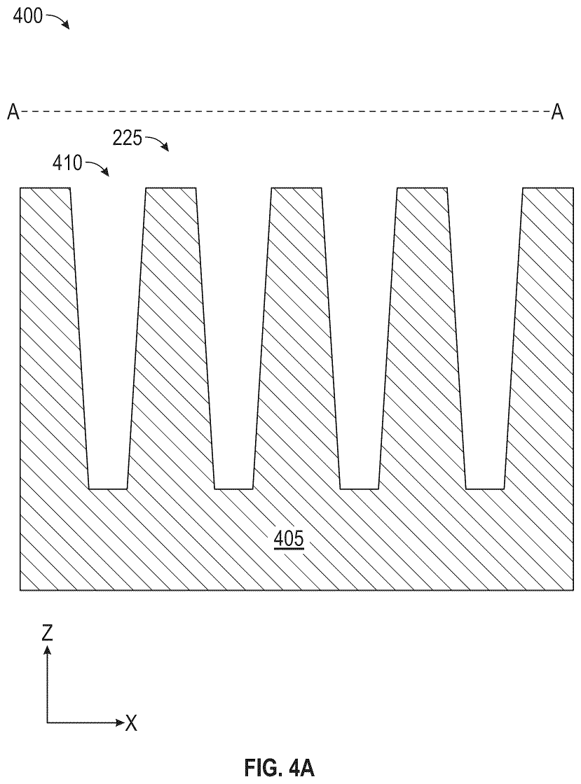

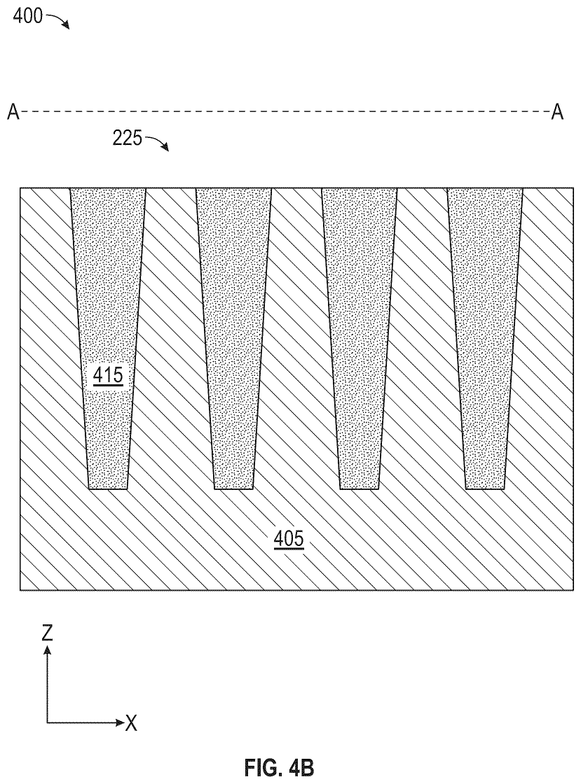

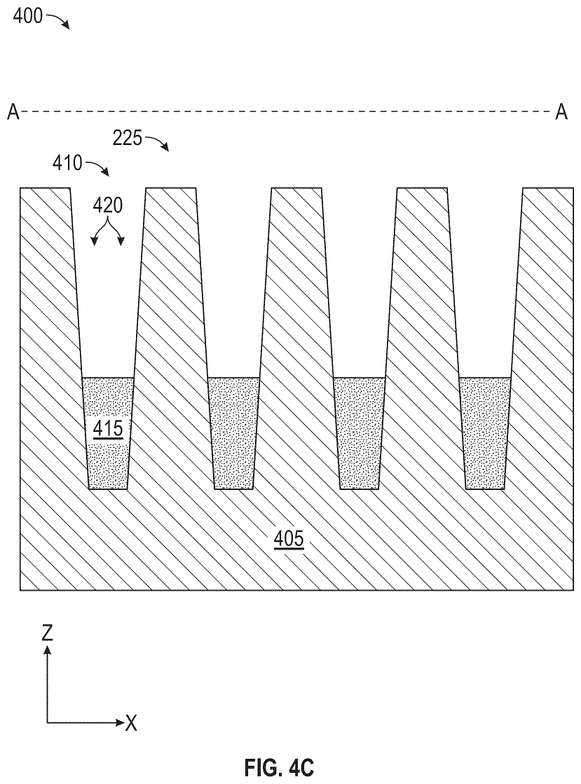

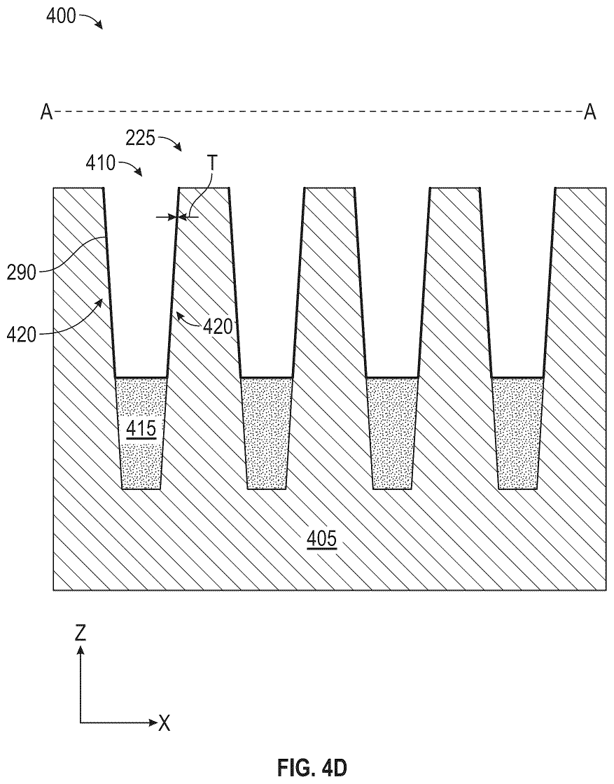

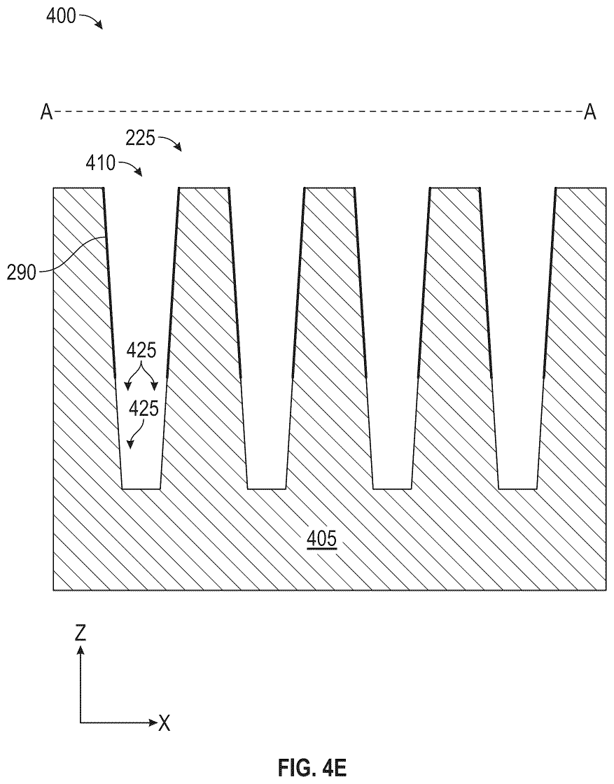

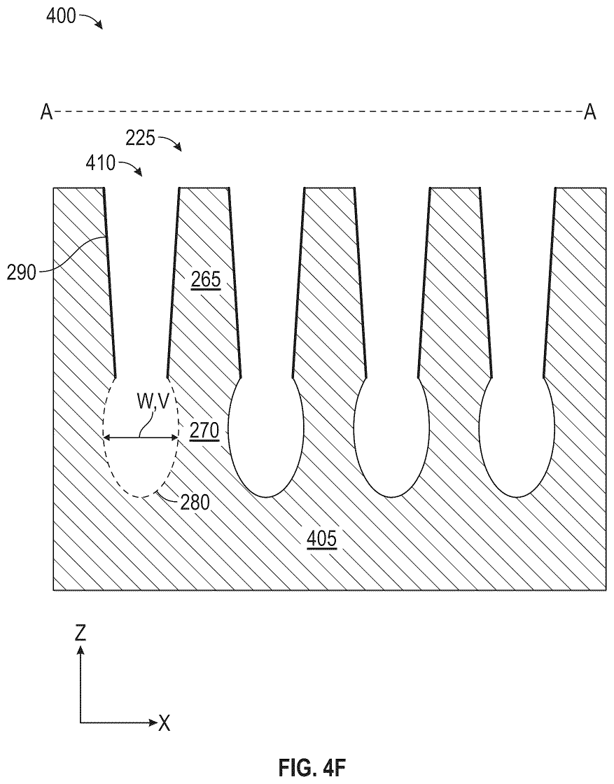

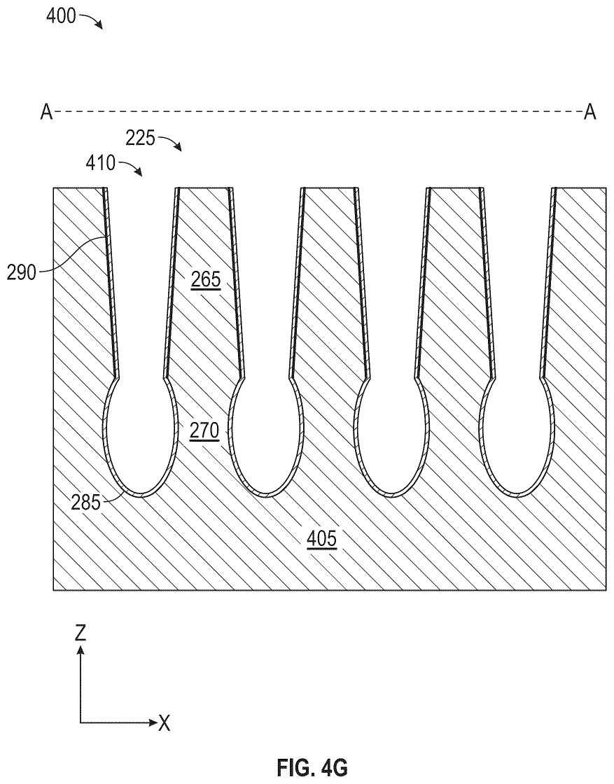

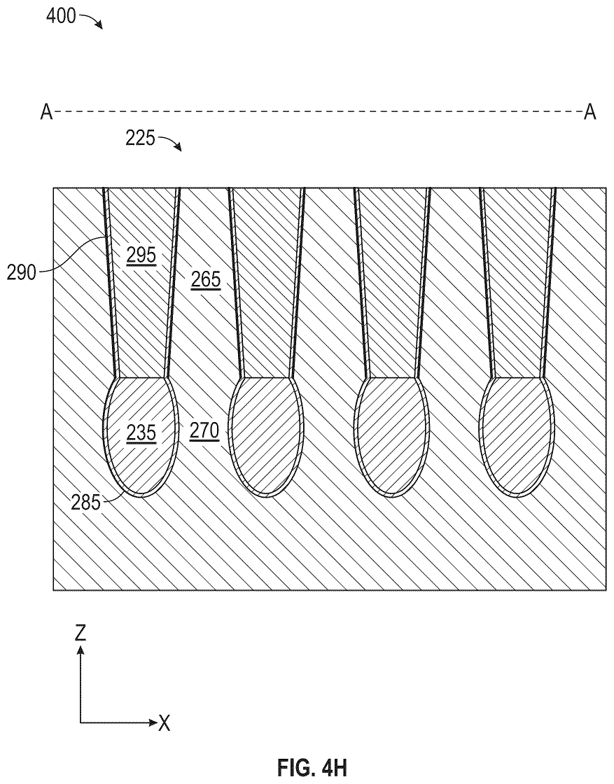

As described in greater detail in connection with FIGS. 3-4H, techniques to form the integrated assembly 205 may result in a combination of geometric shapes and/or dimensional properties of an active area 225 and/or a word line structure 235. For example, and as shown in FIG. 2B, one or more portions of the sidewalls of the upper portion 265-1 of the active area 225-1 may be angled (e.g., angled at an angle θ) relative to a vertical axis 275 passing through the word line structure 235-1. In other words, the upper portion 265-1 may correspond to a tapered region of the active area 225-1. Furthermore, and shown in in FIG. 2B, the upper portion 265-1 includes a base region having a width W1.

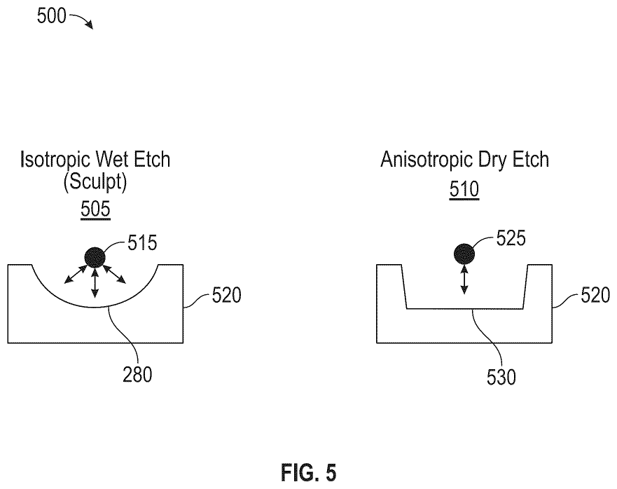

As another example, and shown in FIG. 2B, at least a portion of the sidewalls of the lower portion 270-1 of the active area 225-1 may be concave. In some implementations, and as described in greater detail in connection with FIGS. 4F and 5, the concavity may conform to an isotropic etch profile 280 caused by an isotropic etch process that sculpts a trench between adjacent lower portions 270. Based on the isotropic etch profile 280, at least a portion of the sidewalls of the lower portion 270-1 may be approximately parallel to the vertical axis 275-1 (e.g., along an apex and/or an inflection point of the sidewalls). In some implementations, the lower portion 270-1 has a width W2 that is less than the width W1. In other words, the lower portion 270-1 may correspond to a narrowed region of the active area 225-1.

In some implementations, and based on a spacing of the active areas 225-1 through 225-n, a width of a word line structure 235 may be greater than a width of a lower portion 270. For example, and as shown in FIG. 2B, the width W3 of the word line structure 235-2 is greater than the width W2. However, in some implementations and based on a spacing of the active areas 225-1 through 225-n, the width W3 of a word line structure 235 may be substantially equal to the width W2 or may be less than the width W2.

In some implementations, a dielectric layer 285 may be between a word line structure 235 and a lower portion 270. For example, and as shown in FIG. 2B, the dielectric layer 285 is between the word line structure 235-1 and the lower portion 270-2. The dielectric layer 285 may conform to the isotropic etch profile 280, and include an insulative material as described above. Additionally, or alternatively and in some implementations, the dielectric layer 285 includes an oxide and corresponds to a gate oxide layer. In such a case, the dielectric layer 285 may prevent electrical leakage between the word line structure 235-1 and the lower portion 270.

The integrated assembly 205 may further include a protective layer 290 along sidewalls of an upper portion 265. For example, and as shown in FIG. 2B, the protective layer 290 may be along a sidewall of the upper portion 265-1. As described in greater detail in connection with FIGS. 4D-4F, the protective layer 290 may be a byproduct of techniques used to sculpt trenches that are used to form one or more word line structures 235. In some implementations, the protective layer 290 is a dielectric layer that includes an insulative material as described above.

In some implementations, the dielectric layer 285 may extend below the protective layer 290 and surround a word line structure 235. For example, and as shown in FIG. 2B, the dielectric layer 285 extends below the protective layer 290 and surrounds the word line structure 235-1.

In some implementations, and as shown in FIG. 2B, the integrated assembly includes dielectric structures 295 above word line structures 235. For example, and as shown in FIG. 2B, the dielectric structure 295-1 may be above the word line structure 235-1 and the dielectric structure 295-2 may be above the word line structure 235-2. The dielectric structures 295 may include an insulative material as described above, and electrically isolate the word line structures 235 to enable electrical functionality of the integrated assembly 205.

As indicated above, FIGS. 2A and 2B are provided as an example. Other examples may differ from what is described with respect to FIGS. 2A and 2B.

As described in connection with FIGS. 1, 2A, and 2B, and in some implementations, an integrated assembly (e.g., the integrated assembly 205) includes an active arca region (e.g., the active area 225-1). The active area region includes an upper portion (e.g., the upper portion 265-1) and a lower portion (e.g., the lower portion 270-1), where a width (e.g., the width W2) of the lower portion is less than a width (e.g., the width W1) of the upper portion. The integrated assembly further includes a word line structure (e.g., the word line structure 235-1) horizontally adjacent to the lower portion.

Additionally, or alternatively and in some implementations, an apparatus (e.g., the integrated assembly 205) includes a first semiconductive region (e.g., the active area 225-1) having a first tapered region (e.g., the upper portion 265-1) and a first narrowed region (e.g., the lower portion 270-1) below the first tapered region. The integrated assembly includes a second semiconductive region (e.g., the active area 225-2) having a second tapered region (e.g., the upper portion 265-2) and a second narrowed region below the second tapered region (e.g., the lower portion 270-2). The apparatus further includes and a conductive structure (e.g., the word line structure 235-2) between the first narrowed region and the second narrowed region.

In these ways, a volume of the word line structure is increased to improve a performance and/or a reliability of a memory device including the word line structure. By improving the performance and/or the reliability of the memory device, resources needed to support a product line using the memory device (e.g., semiconductor manufacturing tools, labor, materials, and/or computing resources) may be conserved.

FIG. 3 is a flowchart of an example method 300 of forming an integrated assembly or memory device having a word line structure (e.g., the word line structure 235) formed in sculpted trenches. In some implementations, and as described in greater detail in connection with FIGS. 4A-4H, one or more process blocks of FIG. 3 may be performed by various semiconductor manufacturing equipment.

As shown in FIG. 3, the method 300 may include forming, in silicon, a trench (block 310). As further shown in FIG. 3, the method 300 may include forming a temporary fill structure in the trench (block 320). As further shown in FIG. 3, the method 300 may include recessing the temporary fill structure to expose co-facing surfaces of the silicon and leave a partial fill structure in a bottom portion of the trench (block 330). As further shown in FIG. 3, the method 300 may include forming a protective layer (e.g., the protective layer 290) on the co-facing surfaces and on the partial fill structure (block 340). As further shown in FIG. 3, the method 300 may include removing a portion of the protective layer and the partial fill structure to expose surfaces of the bottom portion of the trench (block 350). As further shown in FIG. 3, the method 300 may include removing additional silicon from the bottom portion of the trench to increase a volume of the bottom portion of the trench (block 360). As further shown in FIG. 3, the method 300 may include forming a word line structure (e.g., the word line structure 235) in the bottom portion of the trench (block 370).

The method 300 may include additional aspects, such as any single aspect or any combination of aspects described below and/or in connection with one or more other methods described elsewhere herein.

In a first aspect, forming the temporary fill structure includes forming the temporary fill structure by depositing a polymer in the trench.

In a second aspect, alone or in combination with the first aspect, forming the protective layer includes forming the protective layer by depositing an oxide layer (e.g., on the co-facing surfaces and the partial fill structure).

In a third aspect, alone or in combination with one or more of the first and second aspects, depositing the oxide layer includes depositing an oxide layer having a thickness that is included in a range of approximately 25 angstroms to approximately 35 angstroms.

In a fourth aspect, alone or in combination with one or more of the first through third aspects, removing the additional silicon includes removing the additional silicon using an isotropic etch process that sculpts the bottom portion of the trench to form an isotropic etch profile (e.g., the isotropic etch profile 280) along sidewalls of the silicon.

In a fifth aspect, alone or in combination with one or more of the first through fourth aspects, the isotropic etch process is a wet, vapor etch process.

In a sixth aspect, alone or in combination with one or more of the first through fifth aspects, the method 300 includes forming an oxide layer in the bottom portion of the trench prior to forming the word line structure,

Although FIG. 3 shows example blocks of the method 300, in some implementations, the method 300 may include additional blocks, fewer blocks, different blocks, or differently arranged blocks than those depicted in FIG. 3. In some implementations, the method 300 may include forming the word line structure 235, an integrated assembly (e.g., the integrated assembly 205) that includes the word line structure 235, any part described herein of the word line structure 235, and/or any part described herein of an integrated assembly that includes the word line structure 235. For example, the method 300 may include forming one or more parts of the memory cell 100.

FIGS. 4A-4H are diagrammatic views showing formation of a word line structure (e.g., the word line structures 235) at stages of an example process 400 described herein. In some implementations, the example process described below in connection with FIGS. 4A-4H may correspond to the method 300 and/or one or more blocks of the method 300. However, the process described below is an example, and other example processes may be used to form the word line structure, an integrated assembly that includes the word line structure, and/or one or more parts of the word line structure and/or the integrated assembly.

As shown in FIG. 4A, the process 400 may include removing (e.g., etching) portions of a semiconductive layer 405 to form trenches 410 that separate active areas 225 within the semiconductive layer 405. As an example, and in some implementations, forming the trenches 410 includes using a combination of lithography and deposition tools to form a pattern of photoresist over the semiconductive layer 405, and using an etch tool to remove portions of the semiconductive layer 405 to form the trenches 410.

As shown in FIG. 4B, the process 400 may include forming (e.g., depositing or growing) a temporary fill structure 415 in the trenches 410. As an example, and in some implementations, forming the temporary fill structure 415 includes a deposition tool depositing a polymer material in trenches 410.

As shown in FIG. 4C, the process 400 may include removing portions of the temporary fill structure 415 to expose co-facing surfaces 420 of the semiconductive layer 405 (e.g., on co-facing surfaces of adjacent active areas 225) and leave partial fill structures (e.g., remaining portions of the temporary fill structure) in the bottom of the trenches 410. As an example, and in some implementations, removing the portions of the temporary fill structure 415 includes an etch tool removing the portions using a timed etch operation to control a depth of removal and leave remaining portions of the temporary fill structure 415 in bottom portions of the trenches 410.

As shown in FIG. 4D, the process 400 may include forming the protective layer 290 on the co-facing surfaces 420 of the semiconductive layer 405 (e.g., on the co-facing surfaces 420 of adjacent active areas 225) and on the partial fill structures (e.g., on the remaining portions of the temporary fills structure 415). As an example, and in some implementations, forming the protective layer 290 includes a deposition tool depositing a dielectric material (e.g., an oxide material) on the co-facing surfaces 420 and on partial fill structures.

In some implementations, a thickness T of the protective layer 290 may be included in a range of approximately 25 angstroms to approximately 35 angstroms. If the thickness T is less than approximately 25 angstroms, protection provided to the co-facing surfaces 420 by the protective layer 290 during a subsequent sculpting operation may be insufficient, and damage to the co-facing surfaces 420 may occur. If the thickness T is greater than approximately 35 angstroms, the protective layer 290 may be overly robust and inhibit removal of the remaining portions of the temporary fill structure 415 prior to the subsequent sculpting operation. However, other values and ranges for the thickness T are within the scope of the present disclosure.

As shown in FIG. 4E, the process 400 may include removing portions of the protective layer 290 over the partial fill structures and exhuming the partial fill structures to expose surfaces 425 at the bottom of the trenches 410. As an example, and in some implementations, removing the portions of the protective layer 290 over the partial fill structures and exhuming the partial fill structures includes an etch tool performing anisotropic (e.g., significantly unidirectional) etch operations.

As shown in FIG. 4F, the process 400 may include removing additional portions of the semiconductive layer 405 from bottom portions of the trenches 410 to increase widths (W) and/or volumes (V) of the bottom portions of the trenches 410. In some implementations, and as described in greater detail in connection with FIG. 5, removing the additional portions of the semiconductive layer 405 includes an etch tool performing an isotropic (e.g., multi-directional) etch operation. As an example, an etch tool may use a wet, vapor etch process to perform the isotropic etch operation and sculpt the bottom portions of the trenches 410, forming the isotropic etch profile 280 along the sidewalls of the semiconductive layer 405.

As shown in FIG. 4G, the process 400 may include forming (e.g., depositing or growing) the dielectric layer 285 (e.g., a gate oxide layer) in the trenches 410. As an example, and in some implementations, forming the dielectric layer 285 includes a deposition tool depositing the dielectric layer 285 on the protective layer 290 and on the sidewalls of the semiconductive layer 405.

As shown in FIG. 4H, the process 400 may include forming (e.g., depositing or growing) word line structures 235 in the bottom portions of the trenches. As an example, and in some implementations, forming the word line structures 235 includes a deposition tool depositing the word line structures 235 over the dielectric layer 285 in the bottom portions of the trenches.

As further shown in FIG. 4H, the process 400 may include forming (e.g., depositing or growing) the dielectric structures 295 above word line structures 235. As an example, and in some implementations, forming the dielectric structures 295 includes a deposition tool depositing the dielectric structures 295 over and/or on the word line structures 235, and a planarization tool planarizing the word line structures 235 after deposition.

As indicated above, the process steps described in connection with FIGS. 4A-4H are provided as examples. Other examples may differ from what is described with respect to FIGS. 4A-4H. The structure shown in FIG. 4H may be equivalent to a portion of the integrated assembly 205 described herein, including the word line structures 235 formed in sculpted trenches.

In process steps above that describe forming material, such material may be formed, for example, using chemical vapor deposition, atomic layer deposition, physical vapor deposition, or another deposition technique. In process steps above that describe removing material, such material may be removed, for example, using a wet etching technique (e.g., wet chemical etching), a dry etching technique (e.g., plasma etching), an ion etching technique (e.g., sputtering or reactive ion etching), atomic layer etching, or another etching technique.

FIG. 5 is a diagrammatic view of example etch operations 500 described herein. The etch operations 500 include an isotropic wet etch operation 505 and an anisotropic dry etch operation 510.

As part of the isotropic wet etch operation 505, an etchant 515 may uniformly remove material from a layer 520 in all directions. The isotropic wet etch operation 505 may form an isotropic morphology corresponding to the isotropic etch profile 280 described in connection with FIGS. 2-4H and elsewhere herein. The isotropic morphology may include surfaces and/or sidewalls that have an approximately spherical, cylindrical, and/or curved shape. Additionally, or alternatively and in some implementations, the isotropic morphology may correspond to a “U-shaped” profile.

In contrast, and as part of the anisotropic dry etch operation 510, an etchant 525 may remove from the layer 520 material in a single direction (e.g., the anisotropic dry etch operation does not remove material in all directions). The anisotropic dry etch operation 510 may form an anisotropic morphology 530. The anisotropic morphology 530 may include surfaces and/or sidewalls that have approximately planar and/or angled shapes.

As indicated above, FIG. 5 is provided as an example. Other examples may differ from what is described with respect to FIG. 5.

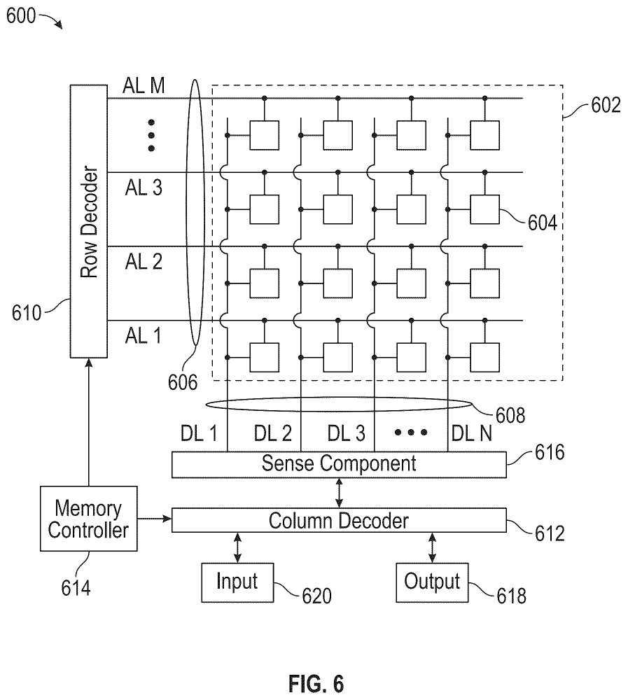

FIG. 6 is a diagrammatic view of an example memory device 600. The memory device 600 may include a memory array 602 that includes multiple memory cells 604. A memory cell 604 is programmable or configurable into a data state of multiple data states (e.g., two or more data states). For example, a memory cell 604 may be set to a particular data state at a particular time, and the memory cell 604 may be set to another data state at another time. A data state may correspond to a value stored by the memory cell 604. The value may be a binary value, such as a binary 0 or a binary 1, or may be a fractional value, such as 0.5, 1.5, or the like. A memory cell 604 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so on.

Operations such as reading and writing (i.e., cycling) may be performed on memory cells 604 by activating or selecting the appropriate access line 606 (shown as access lines AL 1 through AL M) and digit line 608 (shown as digit lines DL 1 through DL N). An access line 606 may also be referred to as a “row line” or a “word line,” and a digit line 608 may also be referred to a “column line” or a “bit line.” Activating or selecting an access line 606 or a digit line 608 may include applying a voltage to the respective line. An access line 606 and/or a digit line 608 may comprise, consist of, or consist essentially of a conductive material, such as a metal (e.g., copper, aluminum, gold, titanium, or tungsten) and/or a metal alloy, among other examples. In FIG. 6, each row of memory cells 604 is connected to a single access line 606, and each column of memory cells 604 is connected to a single digit line 608. By activating one access line 606 and one digit line 608 (e.g., applying a voltage to the access line 606 and digit line 608), a single memory cell 604 may be accessed at (e.g., is accessible via) the intersection of the access line 606 and the digit line 608. The intersection of the access line 606 and the digit line 608 may be called an “address” of a memory cell 604.

In some implementations, the logic storing device of a memory cell 604, such as a capacitor, may be electrically isolated from a corresponding digit line 608 by a selection component, such as a transistor. The access line 606 may be connected to and may control the selection component. For example, the selection component may be a transistor, and the access line 606 may be connected to the gate of the transistor. Activating the access line 606 results in an electrical connection or closed circuit between the capacitor of a memory cell 604 and a corresponding digit line 608. The digit line 608 may then be accessed (e.g., is accessible) to either read from or write to the memory cell 604.

A row decoder 610 and a column decoder 612 may control access to memory cells 604. For example, the row decoder 610 may receive a row address from a memory controller 614 and may activate the appropriate access line 606 based on the received row address. Similarly, the column decoder 612 may receive a column address from the memory controller 614 and may activate the appropriate digit line 608 based on the column address.

Upon accessing a memory cell 604, the memory cell 604 may be read (e.g., sensed) by a sense component 616 to determine the stored data state of the memory cell 604. For example, after accessing the memory cell 604, the capacitor of the memory cell 604 may discharge onto its corresponding digit line 608. Discharging the capacitor may be based on biasing, or applying a voltage, to the capacitor. The discharging may induce a change in the voltage of the digit line 608, which the sense component 616 may compare to a reference voltage (not shown) to determine the stored data state of the memory cell 604. For example, if the digit line 608 has a higher voltage than the reference voltage, then the sense component 616 may determine that the stored data state of the memory cell 604 corresponds to a first value, such as a binary 1. Conversely, if the digit line 608 has a lower voltage than the reference voltage, then the sense component 616 may determine that the stored data state of the memory cell 604 corresponds to a second value, such as a binary 0. The detected data state of the memory cell 604 may then be output (e.g., via the column decoder 612) to an output component 618 (e.g., a data buffer). A memory cell 604 may be written (e.g., set) by activating the appropriate access line 606 and digit line 608. The column decoder 612 may receive data, such as input from input component 620, to be written to one or more memory cells 604. A memory cell 604 may be written by applying a voltage across the capacitor of the memory cell 604.

The memory controller 614 may control the operation (e.g., read, write, re-write, refresh, and/or recovery) of the memory cells 604 via the row decoder 610, the column decoder 612, and/or the sense component 616. The memory controller 614 may generate row address signals and column address signals to activate the desired access line 606 and digit line 608. The memory controller 614 may also generate and control various voltages used during the operation of the memory array 602.

In some implementations, the memory device 600 includes the word line structures 235 and/or an integrated assembly that includes the word line structures. For example, the memory array 602 may include the word line structures 235 and/or the integrated assembly 205. Additionally, or alternatively, the memory cell 604 may include a memory cell described elsewhere herein.

As indicated above, FIG. 6 is provided as an example. Other examples may differ from what is described with respect to FIG. 6.

In some implementations, an integrated assembly includes an active arca region, comprising: an upper portion; and a lower portion, wherein a width of the lower portion is less than a width of the upper portion, and a word line structure horizontally adjacent to the lower portion.

In some implementations, an apparatus includes a first semiconductive region having a first tapered region and a first narrowed region below the first tapered region; a second semiconductive region having a second tapered region and a second narrowed region below the second tapered region; and a conductive structure between the first narrowed region and the second narrowed region.

In some implementations, a method includes forming, in silicon, a trench; forming a temporary fill structure in the trench; recessing the temporary fill structure to expose co-facing surfaces of the silicon and leave a partial fill structure in a bottom portion of the trench; forming a protective layer on the co-facing surfaces and on the partial fill structure; removing a portion of the protective layer and the partial fill structure to expose surfaces of the bottom portion of the trench; removing additional silicon from the bottom portion of the trench to increase a volume of the bottom portion of the trench; and forming a word line structure in the bottom portion of the trench.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like. All ranges described herein are inclusive of numbers at the ends of those ranges, unless specifically indicated otherwise.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An integrated assembly, comprising:
an active area region, comprising:
an upper portion; and
a lower portion,
wherein a width of the lower portion is less than a width of the upper portion, and
a word line structure horizontally adjacent to the lower portion.

2. The integrated assembly of claim 1, wherein a profile of a sidewall of the lower portion corresponds to an isotropic etch profile.

3. The integrated assembly of claim 2, further comprising:
a dielectric layer that is between the word line structure and the lower portion and that conforms to the isotropic etch profile.

4. The integrated assembly of claim 1, wherein at least a portion of a sidewall of the upper portion is angled relative to a vertical axis passing through the word line structure, and
wherein at least a portion of a sidewall of the lower portion is approximately parallel to the vertical axis.

5. The integrated assembly of claim 1, wherein the active area region comprises:
silicon.

6. The integrated assembly of claim 1, wherein the active area region comprises:
a type III-V element.

7. The integrated assembly of claim 1, wherein a width of the word line structure is substantially equal to a width of the lower portion.

8. An apparatus, comprising:
a first semiconductive region having a first tapered region and a first narrowed region below the first tapered region;
a second semiconductive region having a second tapered region and a second narrowed region below the second tapered region; and
a conductive structure between the first narrowed region and the second narrowed region.

9. The apparatus of claim 8, wherein the conductive structure comprises:
titanium nitride.

10. The apparatus of claim 8, wherein a width of the conductive structure is substantially equal to a width of the first narrowed region.

11. The apparatus of claim 8, further comprising:
a first dielectric layer above the conductive structure and adjacent to the first tapered region,
a second dielectric layer between the first tapered region and the first dielectric layer, and
a protective layer between the second dielectric layer and the first tapered region.

12. The apparatus of claim 11, wherein the second dielectric layer extends below the first dielectric layer and surrounds the conductive structure.

13. The apparatus of claim 8, wherein at least a portion of a sidewall of the conductive structure is approximately vertical.

14. A method, comprising:
forming, in silicon, a trench;
forming a temporary fill structure in the trench;
recessing the temporary fill structure to expose co-facing surfaces of the silicon and leave a partial fill structure in a bottom portion of the trench;
forming a protective layer on the co-facing surfaces and on the partial fill structure;
removing a portion of the protective layer and the partial fill structure to expose surfaces of the bottom portion of the trench;
removing additional silicon from the bottom portion of the trench to increase a volume of the bottom portion of the trench; and
forming a word line structure in the bottom portion of the trench.

15. The method of claim 14, wherein forming the temporary fill structure includes:
forming the temporary fill structure by depositing a polymer in the trench.

16. The method of claim 14, wherein forming the protective layer includes:
forming the protective layer by depositing an oxide layer on the co-facing surfaces and the partial fill structure.

17. The method of claim 16, wherein depositing the oxide layer includes:
depositing an oxide layer having a thickness that is included in a range of approximately 25 angstroms to approximately 35 angstroms.

18. The method of claim 14, wherein removing the additional silicon includes:
removing the additional silicon using an isotropic etch process that sculpts the bottom portion of the trench to form an isotropic etch profile along sidewalls of the silicon.

19. The method of claim 18, wherein the isotropic etch process is a wet, vapor etch process.

20. The method of claim 18, further including:
forming an oxide layer in the bottom portion of the trench prior to forming the word line structure.
